(19) United States
(12) Patent Application Publication
(10) Pub. No.: US 2008/0251866 A1
(43) Pub. Date: Oct. 16, 2008

(54) LOW-STRESS HERMETIC DIE ATTACH

(75) Inventors: Ronald A. Belt, Plymouth, MN (US); Doug P. Mortenson, Maple Grove, MN (US)

Correspondence Address: HONEYWELL INTERNATIONAL INC.;PATENT SERVICES AB-2B, 101 COLUMBIA ROAD, P.O. BOX 2245, MORRISTOWN, NJ, 07962-2245, US

(73) Assignee: Honeywell International Inc., Morristown, NJ (US)

(21) Appl. No.: 11/733,415

(22) Filed: Apr. 10, 2007

(51) Int. Cl. H01L 29/84

(52) U.S. Cl. 257/417; 257/E29.324

(57) ABSTRACT

A low-stress hermetic die attach apparatus is disclosed. An example apparatus includes a hermetic package, a device disposed within the hermetic package, and one or more elongated structures greater than 2 thousandths of an inch (mils) in length connected to the package at one end and to the device at the other end. In some embodiments, the apparatus includes elongated structures at least 30 mils long or at least 100 mils long and the device includes a microelectromechanical system (MEMS) die that includes accelerometer or gyro components. In some embodiments, the elongated structures include a column or a pin made of an alloy material such as Kovar. In one embodiment, the Kovar pin is gold plated, attached to the package with a high temperature solder, and attached to the die using gold stud bumps.

### BACKGROUND OF THE INVENTION

Scale factor thermal hysteresis and drift of MEMS gyro sensors and MEMS accelerometers, when packaged in a leadless ceramic chip carrier (LCCC) alumina (Al₂O₃) package, are problematic. Experiments have shown that thermomechanical stress imposed on the gyro or accelerometer by the package is one source of this thermal hysteresis and drift. The thermomechanical stress is caused by a mismatch of the temperature coefficients of expansion (CTE or TCE) between a sensor die (3.6 ppm/° C.) and the alumina package (6.8 ppm/° C.). This stress causes the die to bend while cooling down from 320° C. (the die attachment temperature) to room temperature (25° C.), or while temperature cycling over the range of −55° C. to +85° C. FIG. 1 is a diagram showing a prior art MEMS die gold-bumped into an LCCC package while still at the gold bump die attach temperature of approximately 320° C. After attachment, the gold bumps are typically approximately 3-10 mils in diameter and approximately 2 mils in height. FIG. 2 is a diagram showing the MEMS die of FIG. 1 after it has cooled down to room temperature. FIG. 2 illustrates the problem of bending caused by thermomechanical stress.

The bending of the die causes small changes in the gaps of some capacitors on the die, which changes the scale factor of the sensors. Additional thermomechanical stresses on the package caused by the mismatch of the temperature coefficients of expansion between the alumina package (6.8 ppm/° C.) and a printed wire board (PWB) (17 ppm/° C.) can also be transmitted through the package to the die, causing additional changes of the scale factor with temperature. These thermomechanical stresses can cause both a scale factor hysteresis with temperature and a scale factor drift with time as a result of plastic deformation of the gold bump die attachment or plastic deformation of the package-to-PWB solder joints.

It is known that the problem of die sensitivity to package stress is shared by many other MEMS and non-MEMS devices. Examples of stress-sensitive MEMS devices include: MEMS gyro sensors on silicon or non-silicon substrates, whose zero rate output or scale factor may be sensitive to package stress; MEMS accelerometers on silicon or non-silicon substrates, whose zero rate output or scale factor may be sensitive to package stress; MEMS pressure sensors, whose DC level or scale factor may be sensitive to package stress; MEMS microphones, whose sensitivity may vary with package stress; MEMS light modulators, whose light deflection angles may be sensitive to package stress; and MEMS RF switches, whose threshold voltage may vary with package stress. Examples of stress-sensitive non-MEMS functions include: Infrared (IR) sensors made of various materials, whose softness can lead to damage as a result of package stress; Gallium Arsenide (GaAs) integrated circuits, whose softness can lead to damage as a result of package stress; and some silicon analog circuits whose parameters may be affected by stress-induced changes in MOS transistor conductances, bipolar gains, or resistor values.

More generally, a stress-sensitive die may be any die composed of any type of material (or materials) upon which (or in which) a device is created, one of whose performance parameters is sensitive to the thermomechanical stress imposed upon the die by the package, or from an external source through the package. With respect to MEMS accelerometers and gyros, more conventional means cannot be used to reduce thermomechanical stress on the die because they are either not compatible with hermeticity or are sensitive to vibration and/or high-g forces.

Therefore, there is a need for an apparatus providing reduced thermomechanical stress on devices formed on or in die enclosed within hermetic packages.

### SUMMARY OF THE INVENTION

This invention relates generally to the attachment of stress-sensitive die in hermetic packages and, more specifically, to methods and systems for reducing thermomechanical stress imposed upon the die by the package while maintaining hermeticity and insensitivity to vibration and g-forces.

An apparatus formed in accordance with an example embodiment of the invention includes a hermetic package, a device disposed within the hermetic package, and one or more elongated structures greater than 2 thousandths of an inch (mils) in length connected to the package at one end and to the device at the other end. In accordance with further examples of the invention, an apparatus may be formed that includes elongated structures at least 30 mils long or at least 100 mils long.

In accordance with other examples of the invention, the device includes a microelectromechanical system (MEMS) die. In accordance with still further examples of the invention, the MEMS die includes accelerometer or gyro components.

In accordance with still further examples of the invention, the elongated structures include a solder column or a pin made of an alloy material such as Kovar. In accordance with yet other examples of the invention, the pin includes a gold plated Kovar pin that is attached to the package with a high temperature solder. In accordance with still other examples of the invention, the pin is attached to the die using gold stud bumps.

### BRIEF DESCRIPTION OF THE DRAWINGS

Preferred and alternative embodiments of the present invention are described in detail below with reference to the following drawings:

FIG. 1 is a diagram showing a prior art MEMS die gold-bumped into an LCCC package while still at the gold bump die attach temperature;

FIG. 2 is a diagram showing the MEMS die of FIG. 1 after it has cooled down to room temperature;

FIG. 3 is a diagram showing a top partial x-ray view of an embodiment of the invention;

FIG. 4 is a diagram showing a side cross-sectional view of the embodiment shown in FIG. 3;

FIG. 5 is a diagram of a cross-sectional view illustrating a fixture used to hold pins during attachment in the embodiment of the invention shown in FIGS. 3 and 4;

FIG. 6 is a diagram showing a top partial x-ray view of an alternative embodiment of the invention;

FIG. 7 is a diagram showing a side cross-sectional view of the embodiment shown in FIG. 6;

FIG. 8 is a diagram of a cross-sectional view illustrating a fixture used to hold pins during attachment in the embodiment of the invention shown in FIGS. 6 and 7;

FIG. 9 is a diagram showing a top partial x-ray view of an additional embodiment of the invention;

FIG. 10 is a diagram showing a partially exploded side cross-sectional view of the embodiment shown in FIG. 9; and

FIG. 11 is a diagram of a cross-sectional view illustrating a fixture used to hold pins during attachment in the embodiment of the invention shown in FIGS. 9 and 10.

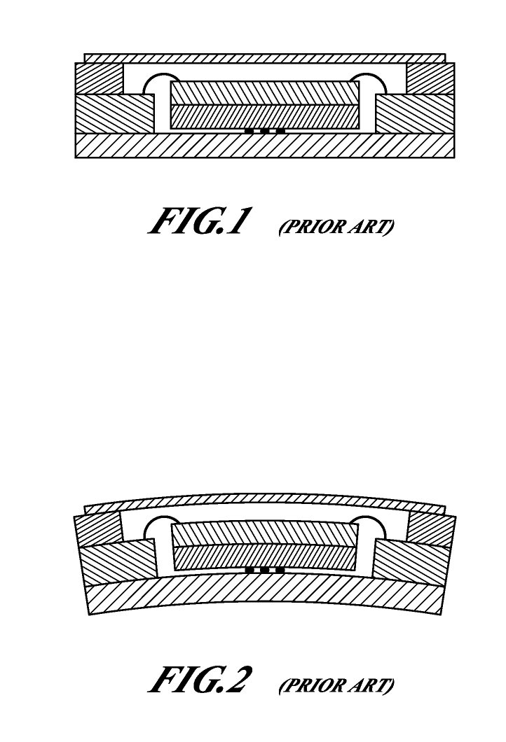

### DETAILED DESCRIPTION OF THE PREFERRED EMBODIMENT

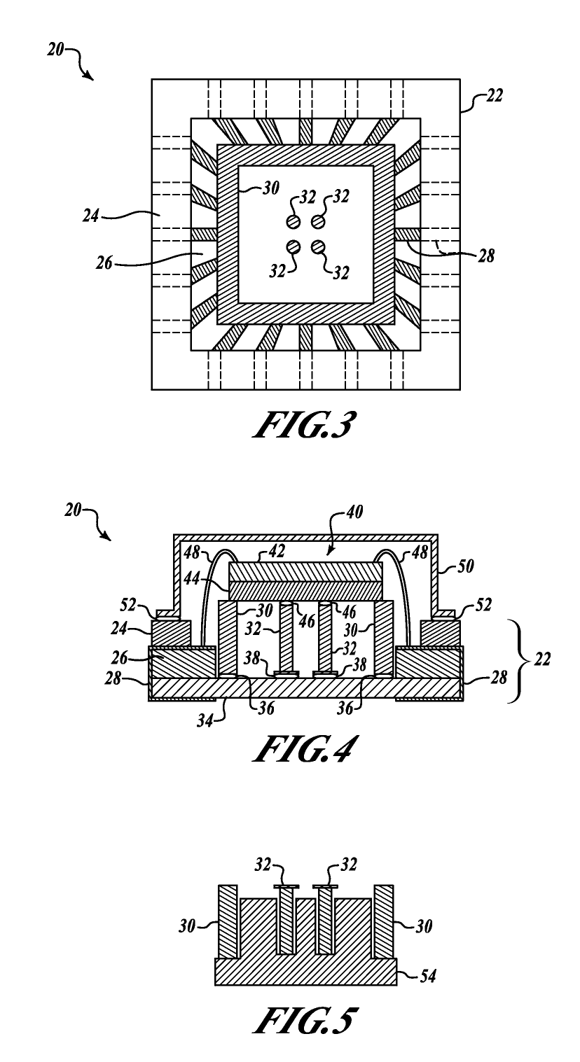

FIGS. 3 and 4 are diagrams showing a top partial x-ray view and a side cross-sectional view respectively of a device 20 formed in accordance with an embodiment of the invention. The device 20 includes a die 40 supported by a plurality of die attach columns 32 located in a package 22. The die attach columns 32 reduce thermomechanical stress and bending effects on the die 40 caused by a mismatch of temperature coefficients of expansion between the die 40 and the package 22. The device 20 also includes a stress relief ring 30 that is used to relieve stress during the attachment of one or more wires 48 between the die 40 and a plurality of package interconnect pins 28.

The device 20 includes the package 22 that is formed of layers of ceramic tape co-fired to bond together in an example embodiment of the invention. The package 22 includes a first layer 24 and a second layer 26 as shown in FIG. 3. The ceramic tape may be made of aluminum oxide, aluminum nitride, sintered aluminum silicon, or a combination of at least one of those materials with a glass material, for example. The package 22 also includes the plurality of package interconnect pins 28 that run through the ceramic layers of the package 22. The pins 28 are formed of molybdenum metal with exposed ends covered in gold for better solderability in an example embodiment. Alternatively, the pins 28 are formed of tungsten or other conductive materials in other embodiments and have exposed ends covered with nickel or other materials rather than gold in some embodiments.

The device 20 also includes the stress relief ring 30 as well as the plurality of die attach columns 32 that are also referred to as elongated structures. The package 22 includes a third layer 34 to which the stress relief ring 30 and the die attach columns 32 are attached. The stress relief ring 30 is attached to the third layer 34 using a stress relief attachment material 36 and the columns 32 are attached using a column attachment material 38. In an example embodiment, the column attachment material 38 is a solder alloy such as Gold/Germanium (AuGe) or Gold/Silicon (AuSi) with a eutectic point or melting point greater than that of any die attach material or lid attach material to be used in the device 20. Alternatively, the column attachment material 38 is a brazing material, a glass die attach material, gold bumps, or an epoxy material. The stress relief attachment material 36 is preferably the same material as the column attachment material 38. However, in some embodiments, the stress relief attachment material 36 includes one of the alternative column attachment materials, or the stress relief ring 30 may be mechanically attached to the package 22 using a press fit rather than by using a stress relief attachment material 36.

The die attach columns 32 are preferably made of gold-plated Kovar, but may include other materials such as ceramic, metal, glass, solder alloys of various compositions, or wire-wrapped solder alloys of various compositions and various wire types. The columns 32 have heights ranging from approximately 5 mils to 200 mils and diameters ranging from approximately 2 mils to 100 mils. In some embodiments, the columns 32 have a head of larger diameter than the central portion of the columns 32 on at least one end. Four columns 32 are preferred, but any number of columns 32 greater than one can be used in the device 20. The stress relief ring 30 is preferably made of gold-plated Kovar, but may include other materials such as ceramic, metal, glass, or comparable material. The stress relief ring 30 has a height ranging from 5 mils to 200 mils. Although the ring 30 is shown as being square, other geometries may be used.

The device 20 also includes the die 40. In an example embodiment, the die 40 includes a stress-sensitive microelectromechanical system (MEMS) device such as a gyroscope or an accelerometer, for example. In some embodiments, the MEMS device includes layers made of silicon, silicon/glass, polysilicon, and/or nickel. In other embodiments, the die 40 includes a gallium arsenide (GaAs) device or other stress-sensitive devices. The die 40 includes a first layer 42 and a second layer 44. The first layer 42 includes silicon and the second layer 44 includes glass, but other materials may be used. The die 40 is attached to the columns 32 using a die attachment material 46. The die attachment material 46 is preferably one or more gold bumps, but may alternatively be a solder alloy with a eutectic point or melting point greater that that of the column attachment material 38 and less that that of a lid attach material used in the device 20. The die attachment material 46 may also include a glass die attach material or an epoxy material. The stress relief ring 30 is not attached to the die 40 in an example embodiment so that the die 40 is able to move relative to the stress relief ring 30 in normal operation, but the stress relief ring 30 is able to provide stress relief for the die 40 during wire bonding and also serve as a stress limiter on the die 40 during high-g accelerations. Pads (not shown) located on the die 40 are electrically connected to the interconnect pins 28 with the one or more wires 48. The wires 48 are gold, aluminum, copper, or one of those metals doped with small amounts of other elements.

The device 20 also includes a package lid 50 that is attached to the package 22 with a lid attach material 52. Although the package 22 and the package lid 50 are discussed separately, they may also be considered to be parts of a single leadless ceramic chip carrier (LCCC) package. In some embodiments, the package 22 and the package lid 50 form a hermetic package. The lid 50 is preferably Kovar plated with nickel and gold to enhance solderability. However, the lid 50 may alternatively be made of Alloy42, silicon, glass, or other package lid material. The lid attach material 52 is preferably gold-tin (AuSn) solder, but may also include any solder alloy having a eutectic point or melting point between approximately 380° C. and 280° C. Alternatively, the lid 50 is attached using other lid attachment techniques such as by using laser welding or seam sealing for example.

FIG. 5 is a diagram of a cross-sectional view illustrating a fixture 54 used to hold the pins 32 and the stress relief ring 30 during attachment to the package 22 in the embodiment of the invention shown in FIGS. 3 and 4. The fixture 54 is made of graphite in an example embodiment, but may be made of other materials such as glass. In one non-limiting embodiment, the fixture 54 has holes drilled into it which are slightly larger in diameter than the columns 32 so that the columns can fit loosely into the holes. The columns 32 are then either hand-placed or machine-placed into the holes. Similarly, the fixture 54 has a relief on the outside which is slightly smaller in dimension than an outer dimension of the stress relief ring 30 so the stress relief ring 30 can fit loosely on the fixture 54. The stress relief ring 30 is then either hand-placed or machine-placed onto the relief of the fixture 54. After the stress relief ring 30 and the columns 32 have been inserted into the fixture 54, a high temperature solder is placed on exposed ends of the columns 32 and the stress relief ring 30, after which the package 22 is placed cavity-down over the fixture 54. The combined package 22 and fixture 54 are then turned right-side up and heated to solder the columns 32 and stress relief ring 30 to a bottom portion of the package 22 cavity. After the columns 32 and stress relief ring 30 have been attached to the package 22, the fixture 54 is removed from the package 22 by sliding it off the columns 32 and the stress relief ring 30.

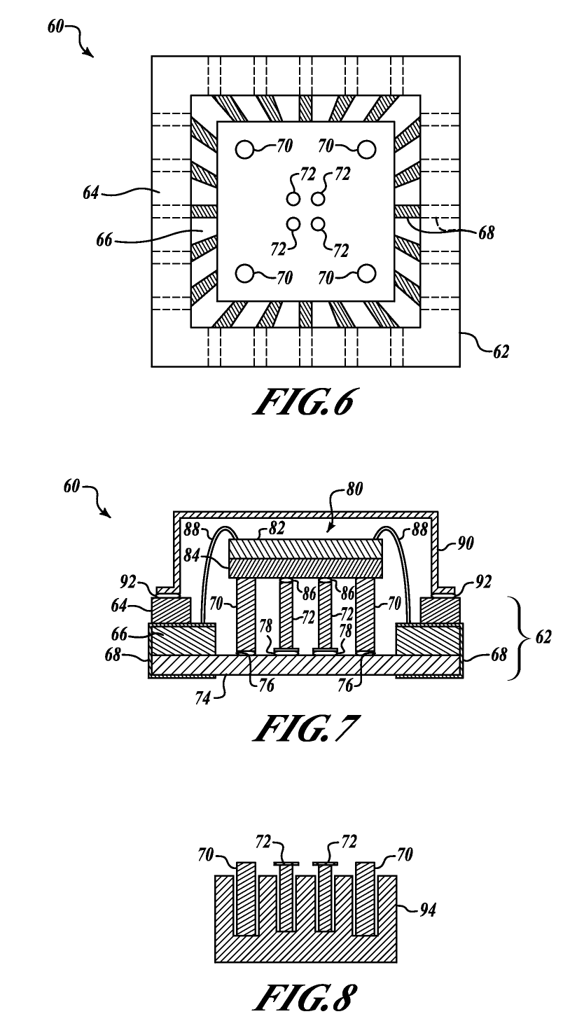

FIGS. 6 and 7 are diagrams showing a top partial x-ray view and a side cross-sectional view respectively of a device 60 formed in accordance with an alternative embodiment of the invention. The device 60 is structured similarly to the device 20 of FIGS. 3 and 4, but the device 60 includes a plurality of stress relief columns rather than a stress relief ring. The device 60 includes a package 62 that is formed of layers of ceramic tape co-fired to bond together in an example embodiment of the invention. A first layer 64 and a second layer 66 are shown in FIG. 6. The ceramic tape may be made of aluminum oxide, aluminum nitride, sintered aluminum silicon, or a combination of at least one of those materials with a glass material, for example. The package 62 also includes a plurality of package interconnect pins 68 that run through the ceramic layers of the package 62. The pins 68 are formed of molybdenum metal with exposed ends covered in gold for better solderability in an example embodiment. Alternatively, the pins 68 are formed of tungsten or other conductive materials in other embodiments and have exposed ends covered with nickel or other materials rather than gold.

The device 60 also includes a plurality of stress relief columns 70 as well as a plurality of die attach columns 72. The package 62 includes a third package layer 74 to which the stress relief columns 70 and the die attach columns 72 are attached. The stress relief columns 70 are attached to the third package layer 74 using a stress relief attachment material 76 and the columns 72 are attached using a column attachment material 78. In an example embodiment, the column attachment material 78 is a solder alloy such as AuGe or AuSi with a eutectic point or melting point greater than that of any die attach material or lid attach material to be used in the device 60. Alternatively, the column attachment material 78 is a brazing material, a glass die attach material, gold bumps, or an epoxy material. The stress relief attachment material 76 is preferably the same material as the column attachment material 78. However, in some embodiments, the stress relief attachment material 76 includes one of the alternative column attachment materials, or the stress relief columns 70 may be mechanically attached to the package 62 using a press fit rather than by using a stress relief attachment material 76.

The die attach columns 72 are preferably made of gold-plated Kovar pins, but may include other materials such as ceramic, metal, glass, solder alloys of various compositions, or wire-wrapped solder alloys of various compositions and various wire types. The columns 72 have heights ranging from approximately 5 mils to 200 mils and diameters ranging from approximately 2 mils to 100 mils. In some embodiments, the columns 72 have a head of larger diameter on at least one end. Four columns 72 are preferred, but any number of columns 72 greater than one can be used in the device 60. The stress relief columns 70 are preferably made of gold-plated Kovar, but may include other materials such as ceramic, metal, or glass for example. The stress relief columns 70 have heights ranging from 5 mils to 200 mils and diameters ranging from 2 mils to 100 mils. In some embodiments, the stress relief columns 70 have a head of larger diameter on at least one end. Four stress relief columns 70 are preferred, but any number of columns greater than one can be used.

The device 60 also includes a die 80. In an example embodiment, the die 80 includes a stress-sensitive microelectromechanical system (MEMS) device such as a gyroscope or an accelerometer, for example. In some embodiments, the MEMS device includes layers made of silicon, silicon/glass, polysilicon, and/or nickel. In other embodiments, the die 80 includes a gallium arsenide (GaAs) device or other stress-sensitive devices. The die 80 includes a first layer 82 and a second layer 84. The first layer 82 includes silicon and the second layer 84 includes glass in an example embodiment. The die 80 is attached to the columns 72 using a die attachment material 86. The die attachment material 86 is preferably one or more gold bumps, but may alternatively be a solder alloy with a eutectic point or melting point greater that that of the column attachment material 78 and less that that of a lid attach material used in the device 60. The die attachment material 86 may also include a glass die attach material or an epoxy material. The stress relief columns 76 are not attached to the die 80 in an example embodiment so that the die 80 is able to move relative to the stress relief columns 76 in normal operation, but the stress relief columns 76 are able to provide stress relief for the die 80 during wire bonding and also serve as a stress limiter on the die 80 during high-g accelerations. Pads (not shown) located on the die 80 are electrically connected to the interconnect pins 68 with one or more wires 88. The wires 88 are gold, aluminum, copper, or one of those metals doped with small amounts of other elements.

The device 60 also includes a package lid 90 that is attached to the package 62 with a lid attach material 92. The lid 90 is preferably Kovar plated with nickel and gold to enhance solderability. However, the lid 90 may alternatively be made of Alloy42, silicon, glass, or other package lid material. The lid attach material 92 is preferably gold-tin (AuSn) solder, but may also include any solder alloy having a eutectic point or melting point between approximately 350° C. and 320° C. Alternatively, the lid 90 is attached using other lid attachment techniques in some embodiments such as by using laser welding or seam sealing for example.

FIG. 8 is a diagram of a cross-sectional view illustrating a fixture used to hold the stress relief columns 70 and the die attach columns 72 during attachment to the package 62 in the embodiment of the invention shown in FIGS. 6 and 7.

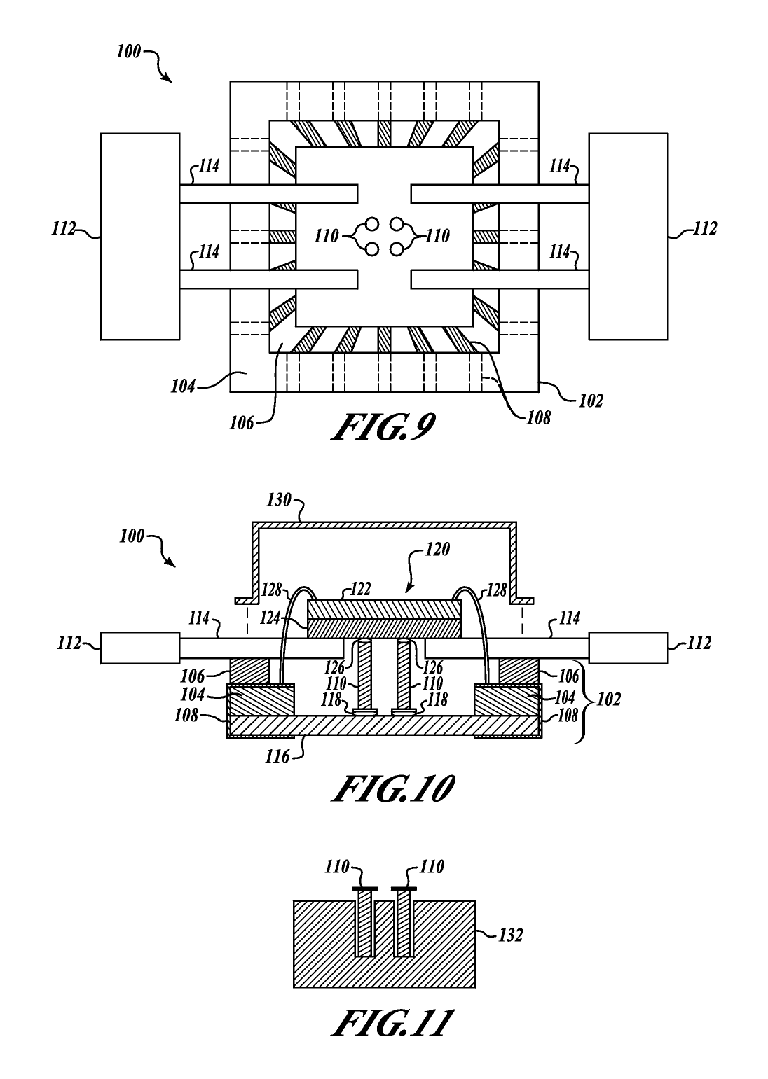

FIGS. 9 and 10 are diagrams showing a top partial x-ray view and a side partially exploded cross-sectional view respectively of a device 100 before final assembly formed in accordance with an additional embodiment of the invention. The device 100 is structured similarly to the device 20 of FIGS. 3 and 4 and the device 60 of FIGS. 6 and 7, but the device 100 uses a temporary comb structure during wire attachment rather than a plurality of stress relief columns or a stress relief ring that remain in the device 100.

The device 100 includes a package 102 that is formed of layers of ceramic tape co-fired to bond together in an example embodiment of the invention. A first layer 104 and a second layer 106 are shown in FIG. 9. The ceramic tape may be made of aluminum oxide, aluminum nitride, sintered aluminum silicon, or a combination of at least one of those materials with a glass material, for example. The package 102 also includes a plurality of package interconnect pins 108 that run through the ceramic layers of the package 102. The pins 108 are formed of molybdenum metal with exposed ends covered in gold for better solderability in an example embodiment. Alternatively, the pins 108 are formed of tungsten or other conductive materials in other embodiments and have exposed ends covered with nickel or other materials rather than gold.

The device 100 also includes a plurality of die attach columns 110. A temporary comb structure 112 that includes a plurality of fingers 114 is used to assist in stabilizing a die during wire attachment. The package 102 includes a third layer 116 to which the die attach columns 110 are attached. The columns 110 are attached using a column attachment material 118. In an example embodiment, the column attachment material 118 is a solder alloy such as AuGe or AuSi with a eutectic point or melting point greater than that of any die attach material or lid attach material to be used in the device 100. Alternatively, the column attachment material 118 is a brazing material, a glass die attach material, gold bumps, or an epoxy material.

The die attach columns 110 are preferably made of gold-plated Kovar pins, but may include other materials such as ceramic, metal, glass, solder alloys of various compositions, or wire-wrapped solder alloys of various compositions and various wire types. The columns 110 have heights ranging from approximately 5 mils to 200 mils and diameters ranging from approximately 2 mils to 100 mils. In some embodiments, the columns 32 have a head of larger diameter on at least one end. Four columns 110 are preferred, but any number of columns 110 greater than one can be used in the device 100.

The device 100 also includes a die 120. In an example embodiment, the die 120 includes a stress-sensitive microelectromechanical system (MEMS) device, such as a gyroscope or accelerometer, for example. In some embodiments, the MEMS device includes layers made of silicon, silicon/glass, polysilicon, and/or nickel. In other embodiments, the die 120 includes a gallium arsenide (GaAs) device or other stress-sensitive devices. The die 120 includes a first layer 122 and a second layer 124. The first layer 122 includes silicon and the second layer 124 includes glass in an example embodiment. The die 120 is attached to the columns 110 using a die attachment material 126. The die attachment material 126 is preferably one or more gold bumps, but may alternatively be a solder alloy with a eutectic point or melting point greater that that of the column attachment material 118 and less that that of a lid attach material used in the device 100. The die attachment material 126 may also include a glass die attach material or an epoxy material. Pads (not shown) located on the die 120 are electrically connected to the interconnect pins 108 with one or more wires 128. The wires 128 are gold, aluminum, copper, or one of those metals doped with small amounts of other elements. The temporary comb structure 112 is used to support the die 120 during attachment of the wires 128.

The device 100 also includes a package lid 130 that is attached to the package 102 with a lid attach material (not shown). The comb structure 112 is removed before the lid 130 is attached. The lid 130 is preferably Kovar plated with nickel and gold to enhance solderability. However, the lid 130 may alternatively be made of Alloy42, silicon, glass, or other package lid material. The lid attach material is preferably gold-tin (AuSn) solder, but may also include any solder alloy having a eutectic point or melting point between approximately 350° C. and 320° C. Alternatively, the lid 130 is attached using other lid attachment techniques such as by using laser welding or seam sealing for example.

FIG. 11 is a diagram of a cross-sectional view illustrating a fixture used to hold pins during attachment in the embodiment of the invention shown in FIGS. 9 and 10.

The following describes melting temperature relationships of various components in an example embodiment of the invention:

T₁=die attach column body melting temperature

T₂=melting temperature of stress ring or stress column to package attachment material

T₃=melting temperature of die attach column to package attachment material

T₄=melting temperature of die attach column to die attachment material

T₅=melting temperature of package lid attachment (=280° C. for Au80Sn20 eutectic solder, or 320° C. oven temperature)

T₆=melting temperature of package attachment to PWB (=183° C. for eutectic Sn63Pb37 solder, or 220° C. oven temperature)

Then one desires: T₁≧T₂≧T₃>T₄>T₅=280° C.>T₆=183° C.

The following paragraphs give a derivation of the degree of stress reduction to be expected on the die as a result of using die attach columns instead of gold bumps. The substrate curvature Rₛ and the chip curvature R_{c} created by the difference in temperature coefficients between the chip and substrate acting while the chip and package are cooling down from the die attach temperature of 320° C. to room temperature are given by equations (1) and (2) as described in T. F. Marinis and J. W. Soucy, “Gold Bump Attachment of MEM Using Thermocompression Bonding”, 53^{rd} Electronic Components and Conference, May 27-30, 2003.

$$\begin{matrix}{R}_{s} = \frac{1}{Δ α Δ T} ( h + \frac{{t}_{c} + {t}_{s}}{2} ) \\ and & ( 1 ) \\ {R}_{c} = {R}_{s} + h + \frac{{t}_{c} + {t}_{s}}{2} = ( h + \frac{{t}_{c} + {t}_{s}}{2} ) ( \frac{1}{Δ α Δ T} + 1 ) & ( 2 )\end{matrix}$$

where the symbols are defined as shown in the table below, with typical values shown. (The simplifying assumption is made that Eₛ=E_{c} and Iₛ=I_{c} in this derivation).

| Symbol | Description | Value | Units |
|---|---|---|---|
| h | standoff height of chip from package | 4.00E−05 | m |
| tₛ | substrate thickness | 6.40E−04 | m |
| t_{c} | chip thickness | 7.60E−04 | m |
| α_{c} | chip coef of temp expansion | 4.1 for | ppm/° C.⁻¹ |
| | | silicon | |
| αₛ | substrate coef of temp expansion | 6.8 for | ppm/° C.⁻¹ |
| | | Al₂O₃ | |
| Δα | differential thermal expansion coef | 3.00E−06 | ppm/° C.⁻¹ |
| Eₛ | Young's modulus for the Al₂O₃ | 378 | Gpa |
| | substrate | | |
| Iₛ | substrate moment of inertia = | 5.5 × 10⁻⁹ | m⁴ |
| | substrate length (1) · substrate width | | |
| | (w)³/12 | | |
| ΔT | temperature change from die attach | 150 | ° C. |
| | temperature to room temperature | | |

Furthermore, shear stress τ₁ in the die attach is given by equation (3).

$${τ}_{1} = - Δ α Δ T \frac{{E}_{s} {I}_{s}}{m {ν}_{0} {t}_{s}} ( \frac{2 h}{h + \frac{{t}_{c} + {t}_{s}}{2}} ) . \qquad ( 3 )$$

In this equation, ν₀ is the volume of a gold bump used for die attach with a value of approximately 4.65×10⁻⁹² m² in an example embodiment.

If the ratios of R_{c} and τ₁ are evaluated with two different standoff heights h₁ and h₂, the following equations are obtained:

$$\begin{matrix}\frac{{R}_{c 1}}{{R}_{c 2}} = [ \frac{2 {h}_{1} + {t}_{c} + {t}_{s}}{2 {h}_{2} + {t}_{c} + {t}_{s}} ] \\ and & ( 4 ) \\ \frac{{τ}_{11}}{{τ}_{12}} = ( \frac{{h}_{1}}{{h}_{2}} ) [ \frac{2 {h}_{2} + {t}_{c} + {t}_{s}}{2 {h}_{1} + {t}_{c} + {t}_{s}} ] . & ( 5 )\end{matrix}$$

From equations (4) and (5), increasing the standoff height of the die from 1.6 mils (the value for gold bumps) to 100 mils (the value for 100 mil high die attach columns) increases the die radius of curvature R_{c} by a factor of 4.3 and reduces the shear stress τ₁ in the die attach by a factor of 14.5.

Generally, it is desirable to use materials for the columns and their attachments to the package and the die which have as little plastic flow and/or creep as possible. That is, it is desired to have these materials remain in the elastic portion of their stress-strain curves. In this way, sensor scale factor hysteresis and drift can be reduced by temperature compensation because the die attach materials retrace their paths with temperature. To assist in achieving this, the columns are made of gold-plated Kovar pins in some embodiments, which can be purchased from companies who make pin-grid array (PGA) packages or micro PGA packages. In other embodiments, columns made of other materials with similar characteristics are used. In an example embodiment, both ends of the columns have flat surfaces to facilitate making stronger bonds to the package and die. One or both ends of the pins have larger diameter heads on them to further facilitate making stronger bonds. Additionally, in some embodiments, die attach column height and diameter are partially determined based on remaining in the elastic portion of the stress-strain curve.

While the preferred embodiment of the invention has been illustrated and described, as noted above, many changes can be made without departing from the spirit and scope of the invention. For example, packages having a different number of layers, or having a conductive layer disposed in a location other than between the second and third layers could be used. Accordingly, the scope of the invention is not limited by the disclosure of the preferred embodiment. Instead, the invention should be determined entirely by reference to the claims that follow.

1. An apparatus comprising:
a package;
a device disposed within the package; and
one or more elongated structures greater than 2 mils in length connected to the package at one end and to the device at the other end.

2. The apparatus of claim 1, wherein the elongated structures are at least 5 mils long.

3. The apparatus of claim 1, wherein the elongated structures are at least 30 mils long.

4. The apparatus of claim 1, wherein the elongated structures are at least 100 mils long.

5. The apparatus of claim 2, wherein the device includes a microelectromechanical system (MEMS) die.

6. The apparatus of claim 5, wherein the die includes at least one of an accelerometer or a gyro.

7. The apparatus of claim 5, wherein the elongated structures include an alloy material.

8. The apparatus of claim 7, wherein the alloy material is Kovar.

9. The apparatus of claim 8, wherein the elongated structure is a pin plated with a metal.

10. The apparatus of claim 9, wherein the metal is gold.

11. The apparatus of claim 10, wherein the pins are attached to the package with a high temperature solder.

12. The apparatus of claim 11, wherein the high temperature solder includes at least one of AuGe or AuSi.

13. The apparatus of claim 11, wherein the package includes a leadless ceramic chip carrier (LCCC) including a lid.

14. The apparatus of claim 13, wherein the LCCC includes an alumina (Al₂O₃) material and the lid includes an alloy material.

15. The apparatus of claim 14, wherein the alloy material of the lid is Kovar.

16. The apparatus of claim 11, wherein the pins are attached to the die using stud bumps.

17. The apparatus of claim 16, wherein the stud bumps include gold.

18. The apparatus of claim 1, further comprising a stress relief component disposed within the package between an inner surface of the package and the device, wherein the stress relief component is attached to the package.

19. The apparatus of claim 18, wherein the stress relief component comprises a stress relief ring that is attached to the package but is not attached to the device.

20. The apparatus of claim 18, wherein the stress relief component comprises a plurality of stress relief columns that are attached to the package but are not attached to the device.
